(19) United States
(12) Patent Application Publication
(10) Pub. No.: US 2026/0113948 A1
(43) Pub. Date: Apr. 23, 2026

(54) SEMICONDUCTOR DEVICE INCLUDING CHARGE TRAP LAYER

(71) Applicant: SK hynix Inc., Gyeonggi-do (KR)

(72) Inventor: Hwan Young KIM, Gyeonggi-do (KR)

(21) Appl. No.: 19/063,302

(22) Filed: Feb. 26, 2025

(30) Foreign Application Priority Data
Oct. 22, 2024 (KR) 10-2024-0144544

(51) Int. Cl. H10B 43/30; H10B 43/27

(52) U.S. Cl. CPC H10B 43/30; H10B 43/27

(57) ABSTRACT

A semiconductor device including a channel pattern and an electrode disposed over the channel pattern. An information storage pattern is disposed between the channel pattern and the electrode. The information storage pattern may include a charge trap layer; a blocking layer between the charge trap layer and the electrode; a first tunnel barrier layer between the charge trap layer and the channel pattern; and a first quantum wall between the charge trap layer and the first tunnel barrier layer. The first tunnel barrier layer may include a material with a higher energy barrier than the charge trap layer. The first quantum wall may include a material with a lower energy barrier than the first tunnel barrier layer.

### CROSS-REFERENCE TO RELATED APPLICATION

The present application claims priority under 35 U.S.C. § 119(a) to Korean Patent Application No. 10-2024-0144544 filed on Oct. 22, 2024, which is incorporated herein by reference in its entirety.

### BACKGROUND

### 1. Technical Field

Embodiments of the present disclosure relate generally to a semiconductor device and, more particularly, to a semiconductor device including a charge trap layer and a method of forming the same.

### 2. Related Art

Nonvolatile memory devices such as flash memory are memory that retains stored data even when power is cut off. Various technologies are being attempted for high integration of nonvolatile memory devices. Increasing the operating speed and minimizing power consumption of nonvolatile memory devices are facing various technical limitations.

### SUMMARY

Embodiments of the present disclosure are directed to providing a semiconductor device including a charge trap layer, and a method of forming the same.

In an embodiment of the present disclosure, a semiconductor device may include a channel pattern. An electrode may be disposed over the channel pattern. An information storage pattern may be disposed between the channel pattern and the electrode. The information storage pattern may include a charge trap layer; a blocking layer between the charge trap layer and the electrode; a first tunnel barrier layer between the charge trap layer and the channel pattern; and a first quantum wall between the charge trap layer and the first tunnel barrier layer. The first tunnel barrier layer may include a material with a higher energy barrier than the charge trap layer. The first quantum wall may include a material with a lower energy barrier than the first tunnel barrier layer.

In an embodiment of the present disclosure, a semiconductor device may include a stack structure having a plurality of molding layers and a plurality of horizontal electrodes that are alternately stacked. A source line may be disposed on the stack structure. A channel structure passing through the stack structure and extending into the source line may be provided. The channel structure may include a channel pattern contacting the source line; and an information storage pattern between the channel pattern and the stack structure. The information storage pattern may include a charge trap layer; a blocking layer between the charge trap layer and the stack structure; a first tunnel barrier layer between the charge trap layer and the channel pattern; and a first quantum wall between the charge trap layer and the first tunnel barrier layer. The first tunnel barrier layer may include a material with a higher energy barrier than the charge trap layer. The first quantum wall may include a material with a lower energy barrier than the first tunnel barrier layer.

According to embodiments of the present disclosure, it is possible to implement a semiconductor device that is advantageous for high-speed operation, is capable of high-speed switching and achieves low power consumption.

These and other features and advantages of the present invention will become apparent to those with ordinary skill in the art from the detailed description of embodiments and the following figures.

### BRIEF DESCRIPTION OF THE DRAWINGS

FIG. 1 to FIG. 3, FIG. 5 and FIG. 7 are cross-sectional views illustrating semiconductor devices according to embodiments of the present disclosure.

FIG. 4 and FIG. 6 are plan views illustrating semiconductor devices according to embodiments of the present disclosure.

FIG. 8 to FIG. 13 are cross-sectional views illustrating a method of forming a semiconductor device according to embodiments of the present disclosure.

### DETAILED DESCRIPTION

Embodiments of the present disclosure are described in detail with reference to the accompanying drawings. Specific structural or functional descriptions of the embodiments are provided as examples to describe concepts that are disclosed in the present application. Embodiments in accordance with the concepts of the present disclosure may be carried out in various forms, and the scope of the present disclosure is not limited to the embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

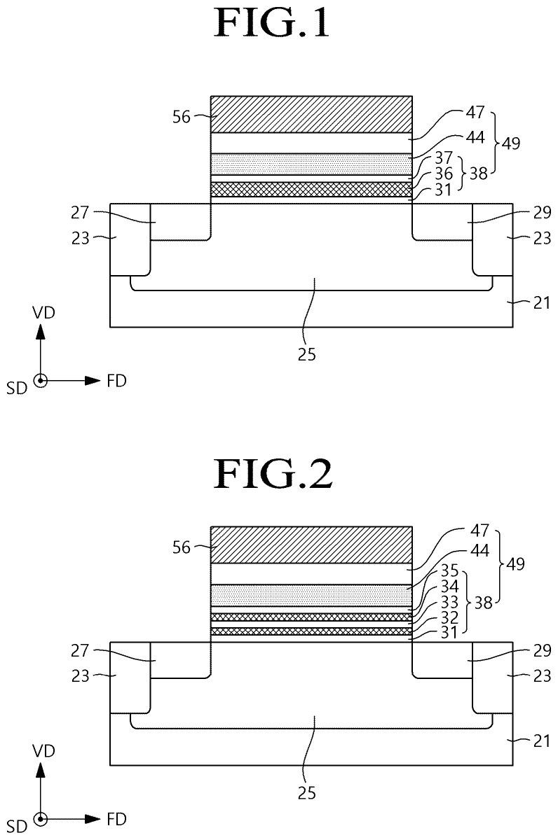

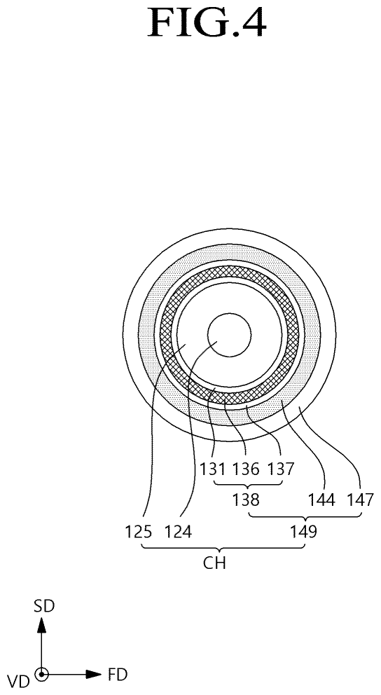

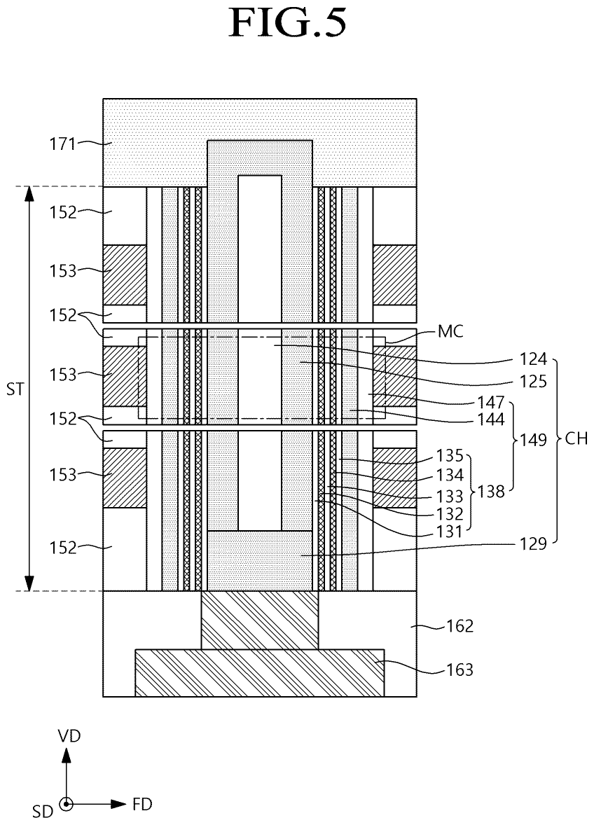

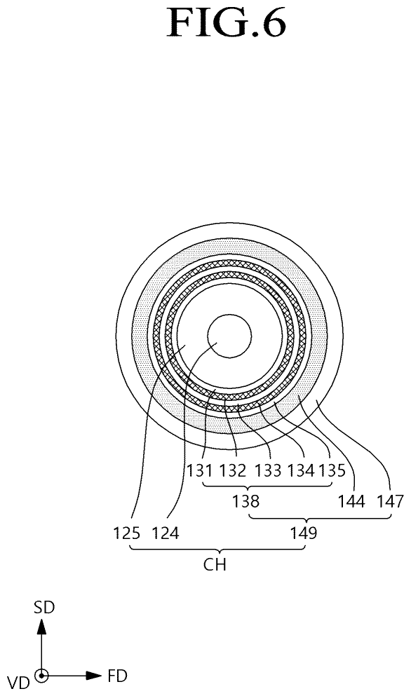

FIG. 1 to FIG. 3, FIG. 5 and FIG. 7 are cross-sectional views and FIG. 4 and FIG. 6 are plan views illustrating semiconductor devices according to embodiments of the present disclosure. In an embodiment, the semiconductor device may include a nonvolatile memory device such as flash memory.

Referring to FIG. 1, a semiconductor device according to embodiments of the present disclosure may include a first substrate 21, an isolation layer 23, a channel pattern 25, a source region 27, a drain region 29, an information storage pattern 49, and a top electrode 56.

The information storage pattern 49 may include a tunnel layer 38, a charge trap layer 44 and a blocking layer 47. The tunnel layer 38 may include a tunnel barrier layer 31, a quantum wall 36 and a ferroelectric layer 37.

A first direction FD, a second direction SD and a third direction VD may be defined. The second direction SD may intersect the first direction FD. The third direction VD may intersect the first direction FD and the second direction SD. In an embodiment, the first direction FD and the second direction SD may be parallel to the upper surface (or top surface) and the lower surface (or bottom surface) of the first substrate 21. The third direction VD may be perpendicular to the upper surface and the lower surface of the first substrate 21. The second direction SD may be perpendicular to the first direction FD. The third direction VD may be perpendicular to the first direction FD and the second direction SD.

The channel pattern 25, the source region 27 and the drain region 29 may be delimited by the isolation layer 23 in the first substrate 21. The channel pattern 25 may be disposed between the source region 27 and the drain region 29. In an embodiment, the channel pattern 25 may include a semiconductor layer that has P-type impurities. The channel pattern 25 may include a monocrystalline silicon layer, a polysilicon layer or a combination thereof, having P-type impurities. Each of the source region 27 and the drain region 29 may include a semiconductor layer that has N-type impurities. Each of the source region 27 and the drain region 29 may include a monocrystalline silicon layer, a polysilicon layer or a combination thereof, having N-type impurities.

The information storage pattern 49 may be disposed in the third direction VD on the channel pattern 25. The top electrode 56 may be disposed in the third direction VD on the information storage pattern 49. The information storage pattern 49 may be interposed between the top electrode 56 and the channel pattern 25. In an embodiment, the channel pattern 25, the information storage pattern 49 and the top electrode 56 may configure a nonvolatile memory cell. The top electrode 56 may be connected to a word line (not illustrated). The top electrode 56 may correspond to a section of the word line.

The tunnel layer 38, the charge trap layer 44 and the blocking layer 47 may be sequentially stacked in the third direction VD. The charge trap layer 44 may be disposed between the tunnel layer 38 and the blocking layer 47. The blocking layer 47 may be disposed between the charge trap layer 44 and the top electrode 56. The blocking layer 47 may contact the top electrode 56.

The tunnel layer 38 may be disposed on the channel pattern 25. The tunnel barrier layer 31, the quantum wall 36 and the ferroelectric layer 37 may be sequentially stacked over the channel pattern 25. The quantum wall 36 may be interposed between the tunnel barrier layer 31 and the ferroelectric layer 37. The tunnel barrier layer 31 may contact the channel pattern 25. The ferroelectric layer 37 may contact the charge trap layer 44.

The tunnel barrier layer 31 may include a material with a higher energy barrier than the quantum wall 36. The tunnel barrier layer 31 may include a material with a higher energy barrier than the ferroelectric layer 37. The tunnel barrier layer 31 may include a material with a higher energy barrier than the charge trap layer 44. The tunnel barrier layer 31 may include silicon oxide, aluminum oxide (Al₂O₃), silicon nitride (Si₃N₄), boron nitride (BN), titanium oxide (TiO₂), zirconium oxide (ZrO₂), magnesium oxide (MgO), gallium nitride (GaN), or a combination thereof. The tunnel barrier layer 31 may have a thickness of 0.5 nm to 10 nm.

In an embodiment, the tunnel barrier layer 31 may include a silicon oxide layer. The tunnel barrier layer 31 may have a thickness of 1 nm to 10 nm. When the thickness of the tunnel barrier layer 31 is less than 0.5 nm, various issues, such as increase in the process dispersion and increase in the leakage current, may occur. When the thickness of the tunnel barrier layer 31 is greater than 10 nm, various issues may occur, such as, for example, an increase in the operating voltage and a decrease in the current driving capability.

The quantum wall 36 may include a material with a lower energy barrier than the tunnel barrier layer 31. The quantum wall 36 may include a material with a lower energy barrier than the ferroelectric layer 37. The quantum wall 36 may include a material with a lower energy barrier than the charge trap layer 44. The quantum wall 36 may include tantalum pentoxide (Ta₂O₅), aluminum nitride (AlN), zirconium oxide (ZrO₂), strontium titanate (SrTiO₃), yttrium oxide (Y2O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof. The quantum wall 36 may have a thickness of 0.5 nm to 20 nm.

In an embodiment, the quantum wall 36 may be in direct contact with the tunnel barrier layer 31 and the ferroelectric layer 37. The quantum wall 36 may include a tantalum pentoxide (Ta₂O₅) layer. The quantum wall 36 may have a thickness of 1 nm to 20 nm. When the thickness of the quantum wall 36 is less than 0.5 nm, various issues such as increase in the process dispersion and increase in the leakage current may occur. When the thickness of the quantum wall 36 is greater than 20 nm, various issues such as increase in the operating voltage and decrease in the current driving capability may occur.

The ferroelectric layer 37 may include a material with a higher energy barrier than the quantum wall 36. The ferroelectric layer 37 may include a material with a higher energy barrier than the charge trap layer 44. The ferroelectric layer 37 may include a material with a lower energy barrier than the tunnel barrier layer 31. The ferroelectric layer 37 may include hafnium oxide (HfO₂), hafnium zirconium oxide (HfZrO₂), lead zirconate titanate (PZT), bismuth ferrite (BiFeO₃), strontium bismuth tantalate (SBT) (SrBi₂Ta₂O₉), lithium niobate (LiNbO₃), barium titanate (BaTiO₃), titanium nitride (TiN), zirconium oxide (ZrO₂), strontium titanate (SrTiO₃), hafnium oxide doped with silicon (Si) or aluminum (Al), or a combination thereof. The ferroelectric layer 37 may have a thickness of 0.5 nm to 10 nm.

In an embodiment, the ferroelectric layer 37 may include a hafnium oxide (HfO₂) layer. The ferroelectric layer 37 may have a thickness of 1 nm to 10 nm. When the thickness of the ferroelectric layer 37 is less than 0.5 nm, various issues such as increase in the process dispersion and increase in the leakage current may occur. When the thickness of the ferroelectric layer 37 is greater than 10 nm, various issues such as increase in the operating voltage and decrease in the current driving capability may occur.

The charge trap layer 44 may include a material with a lower energy barrier than the blocking layer 47. The charge trap layer 44 may include a material with a lower energy barrier than the ferroelectric layer 37. The charge trap layer 44 may include silicon nitride. The charge trap layer 44 may have a thickness of 1 nm to 30 nm. The blocking layer 47 may include a material with a higher energy barrier than the charge trap layer 44. In an embodiment, the blocking layer 47 may include an aluminum oxide (Al2O3) layer. The blocking layer 47 may have a thickness of 3 nm to 30 nm.

In an embodiment, the tunnel layer 38 according to the embodiments of the present disclosure may correspond to a resonant tunnel layer. While a program operation of the semiconductor device according to the embodiments of the present disclosure is performed, electrons that pass through the tunnel layer 38 from the channel pattern 25 may be injected into the charge trap layer 44. The resonant energy level of electrons that pass through the tunnel layer 38 may be determined by the combination of the tunnel barrier layer 31, the quantum wall 36 and the ferroelectric layer 37. The combination of the tunnel barrier layer 31, the quantum wall 36 and the ferroelectric layer 37 may control the amount of electrons that are injected into the charge trap layer 44, by using a relatively small energy level gap. The on/off characteristics of a nonvolatile memory device may be improved. In a nonvolatile memory device, a relatively large number of level states may be implemented.

Referring to FIG. 2, a semiconductor device according to embodiments of the present disclosure may include a first substrate 21, an isolation layer 23, a channel pattern 25, a source region 27, a drain region 29, an information storage pattern 49, and a top electrode 56.

The information storage pattern 49 may include a tunnel layer 38, a charge trap layer 44 and a blocking layer 47 with the charge trap layer 44 disposed between the tunnel layer 38 and the blocking layer 47. The tunnel layer 38 may include a first tunnel barrier layer 31, a first quantum wall 32, a second tunnel barrier layer 33, a second quantum wall 34, and a third tunnel barrier layer 35. The first tunnel barrier layer 31, the first quantum wall 32, the second tunnel barrier layer 33, the second quantum wall 34 and the third tunnel barrier layer 35 may be sequentially stacked. The first tunnel barrier layer 31 may contact the channel pattern 25. The first quantum wall 32 may be interposed between the first tunnel barrier layer 31 and the second tunnel barrier layer 33. The first quantum wall 32 may be in direct contact with the first tunnel barrier layer 31 and the second tunnel barrier layer 33. The second quantum wall 34 may be interposed between the second tunnel barrier layer 33 and the third tunnel barrier layer 35. The second quantum wall 34 may be in direct contact with the second tunnel barrier layer 33 and the third tunnel barrier layer 35. The third tunnel barrier layer 35 may contact the charge trap layer 44.

The first tunnel barrier layer 31 may include a material with a higher energy barrier than the first quantum wall 32. The first tunnel barrier layer 31 may include a material with a higher energy barrier than the second quantum wall 32. The first tunnel barrier layer 31 may include a material with a higher energy barrier than the charge trap layer 44. The first tunnel barrier layer 31 may include silicon oxide, aluminum oxide (Al₂O₃), silicon nitride (Si₃N₄), boron nitride (BN), titanium oxide (TiO₂), zirconium oxide (ZrO₂), magnesium oxide (MgO), gallium nitride (GaN), or a combination thereof. The first tunnel barrier layer 31 may have a thickness of 0.5 nm to 5 nm.

In an embodiment, the first tunnel barrier layer 31 may include a silicon oxide layer. The first tunnel barrier layer 31 may have a thickness of 1 nm to 5 nm. When the thickness of the first tunnel barrier layer 31 is less than 0.5 nm, various issues such as increase in the process dispersion and increase in the leakage current may occur. When the thickness of the first tunnel barrier layer 31 is larger than 5 nm, various issues such as increase in the operating voltage and decrease in the current driving capability may occur.

The first quantum wall 32 may include a material with a lower energy barrier than the first tunnel barrier layer 31. The first quantum wall 32 may include a material with a lower energy barrier than the second tunnel barrier layer 33 and the third tunnel barrier layer 35. The first quantum wall 32 may include a material with a lower energy barrier than the charge trap layer 44. The first quantum wall 32 may include tantalum pentoxide (Ta₂O₅), aluminum nitride (AlN), zirconium oxide (ZrO₂), strontium titanate (SrTiO₃), yttrium oxide (Y2O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof. The first quantum wall 32 may have a thickness of 0.5 nm to 7 nm.

In an embodiment, the first quantum wall 32 may include a tantalum pentoxide (Ta₂O₅) layer. The first quantum wall 32 may have a thickness of 1 nm to 7 nm. When the thickness of the first quantum wall 32 is less than 0.5 nm, various issues such as increase in the process dispersion and increase in the leakage current may occur. When the thickness of the first quantum wall 32 is larger than 7 nm, various issues such as increase in the operating voltage and decrease in the current driving capability may occur.

The second tunnel barrier layer 33 may include a material with a higher energy barrier than the first quantum wall 32. The second tunnel barrier layer 33 may include a material with a higher energy barrier than the second quantum wall 34. The second tunnel barrier layer 33 may include a material with a higher energy barrier than the charge trap layer 44. The second tunnel barrier layer 33 may include silicon oxide, aluminum oxide, silicon nitride (Si₃N₄), boron nitride (BN), titanium oxide (TiO₂), zirconium oxide (ZrO₂), magnesium oxide (MgO), gallium nitride (GaN), or a combination thereof. The second tunnel barrier layer 33 may have a thickness of 0.5 nm to 5 nm.

In an embodiment, the second tunnel barrier layer 33 may include a silicon oxide layer. The second tunnel barrier layer 33 may have a thickness of 1 nm to 5 nm. When the thickness of the second tunnel barrier layer 33 is less than 0.5 nm, various issues such as increase in the process dispersion and increase in the leakage current may occur. When the thickness of the second tunnel barrier layer 33 is greater than 5 nm, various issues such as increase in the operating voltage and decrease in the current driving capability may occur.

The second quantum wall 34 may include a material with a lower energy barrier than the second tunnel barrier layer 33. The second quantum wall 34 may include a material with a lower energy barrier than the third tunnel barrier layer 35. The second quantum wall 34 may include a material with a lower energy barrier than the first tunnel barrier layer 31. The second quantum wall 34 may include a material with a lower energy barrier than the charge trap layer 44. The second quantum wall 34 may include tantalum pentoxide (Ta₂O₅), aluminum nitride (AlN), zirconium oxide (ZrO₂), strontium titanate (SrTiO₃), yttrium oxide (Y₂O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof. The second quantum wall 34 may have a thickness of 0.5 nm to 7 nm.

In an embodiment, the second quantum wall 34 may include a tantalum pentoxide (Ta₂O₅) layer. The second quantum wall 34 may have a thickness of 1 nm to 7 nm. When the thickness of the second quantum wall 34 is less than 0.5 nm, various issues such as increase in the process dispersion and increase in the leakage current may occur. When the thickness of the second quantum wall 34 is larger than 7 nm, various issues such as increase in the operating voltage and decrease in the current driving capability may occur.

The third tunnel barrier layer 35 may include a material with a higher energy barrier than the second quantum wall 34. The third tunnel barrier layer 35 may include a material with a higher energy barrier than the first quantum wall 32. The third tunnel barrier layer 35 may include a material with a higher energy barrier than the charge trap layer 44. The third tunnel barrier layer 35 may include silicon oxide, aluminum oxide (Al₂0₃), silicon nitride (Si₃N₄), boron nitride (BN), titanium oxide (TiO₂), zirconium oxide (ZrO₂), magnesium oxide (MgO), gallium nitride (GaN), or a combination thereof. The third tunnel barrier layer 35 may have a thickness of 0.5 nm to 5 nm.

In an embodiment, the third tunnel barrier layer 35 may include a silicon oxide layer. The third tunnel barrier layer 35 may have a thickness of 1 nm to 5 nm. When the thickness of the third tunnel barrier layer 35 is less than 0.5 nm, various issues such as increase in the process dispersion and increase in the leakage current may occur. When the thickness of the third tunnel barrier layer 35 is greater than 5 nm, various issues such as increase in the operating voltage and decrease in the current driving capability may occur.

In an embodiment, the tunnel layer 38 may correspond to a barrier-controlled resonant tunneling (BCRT) layer. The barrier-controlled resonant tunneling (BCRT) layer may serve to, in an off state, maintain a high wall and confine charges well. In an on state, the barrier-controlled resonant tunneling (BCRT) layer maintains a high wall, and electrons resonantly tunnel between two quantum wall states. Thus, electrons may pass easily even with less energy. The barrier-controlled resonant tunneling (BCRT) layer may serve to allow a relatively large amount of electrons to pass with a relatively low voltage and move to the charge trap layer 44. While a program operation of the semiconductor device according to the embodiments of the present disclosure is performed, electrons that pass through the tunnel layer 38 from the channel pattern 25 may be injected into the charge trap layer 44. The on/off characteristics of a nonvolatile memory device may be improved. In the nonvolatile memory device, a relatively large number of level states may be implemented. In the nonvolatile memory device, a write/erase voltage may be reduced. In the nonvolatile memory device, a write/erase speed may increase.

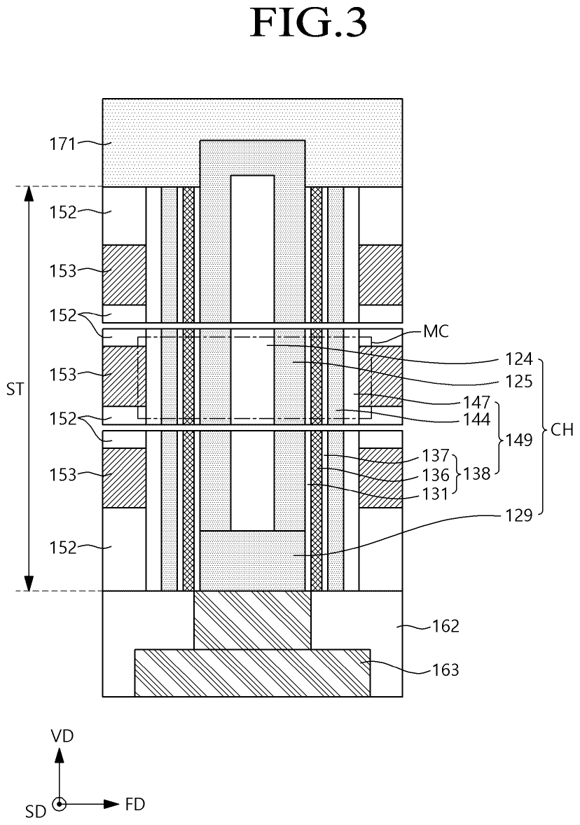

Referring to FIG. 3, a semiconductor device according to embodiments of the present disclosure may include a stack structure ST, a channel structure CH, an interlayer insulating layer 162, a bit line 163, and a source line 171. FIG. 3 corresponds to a cross-sectional view taken on a plane that is defined in the first direction FD and the third direction VD.

The stack structure ST may include a plurality of molding layers 152 and a plurality of horizontal electrodes 153 that are alternately stacked in the third direction VD. The uppermost layer and the lowermost layer of the stack structure ST may be molding layers 152. The source line 171 may be disposed in the third direction VD on the stack structure ST.

The channel structure CH may include a core layer 124, a channel pattern 125, a drain pad 129 and an information storage pattern 149. The information storage pattern 149 may include a tunnel layer 138, a charge trap layer 144 and a blocking layer 147. The tunnel layer 138 may include a tunnel barrier layer 131, a quantum wall 136 and a ferroelectric layer 137.

The channel structure CH may extend into the source line 171 by passing through the stack structure ST in the third direction VD. The core layer 124 may extend into the source line 171 by passing through the stack structure ST in the third direction VD. The channel pattern 125 may surround the side surface and the upper surface of the core layer 124. The channel pattern 125 may extend into the source line 171. The channel pattern 125 may be in direct contact with the source line 171. The channel pattern 125 may surround the side surface and the top surface of the core layer 124.

The information storage pattern 149 may surround the side surface of the channel pattern 125. The channel pattern 125 may be disposed between the information storage pattern 149 and the core layer 124. In an embodiment, the channel pattern 125 also may include a portion which extends inside the source line 171 to cover the top surface of the core layer 124. The information storage pattern 149 may be disposed between the channel pattern 125 and the stack structure ST. The information storage pattern 149 may include a configuration similar to that described above with reference to FIG. 1.

In an embodiment, the tunnel layer 138 may be disposed on the side surface of the channel pattern 125 in the first direction FD. The tunnel layer 138 may contact the channel pattern 125. The tunnel layer 138 may be disposed between the channel pattern 125 and the charge trap layer 144. The tunnel barrier layer 131 may be disposed between the channel pattern 125 and the quantum wall 136. The tunnel barrier layer 131 may contact the channel pattern 125. The quantum wall 136 may be interposed between the tunnel barrier layer 131 and the ferroelectric layer 137. The quantum wall 136 may be in direct contact with the tunnel barrier layer 131 and the ferroelectric layer 137. The ferroelectric layer 137 may be disposed between the quantum wall 136 and the charge trap layer 144. The ferroelectric layer 137 may contact the charge trap layer 144.

The charge trap layer 144 may be disposed on the side surface of the ferroelectric layer 137 in the first direction FD. The charge trap layer 144 may be disposed between the tunnel layer 138 and the blocking layer 147. The blocking layer 147 may be disposed on the side surface of the charge trap layer 144 in the first direction FD. The blocking layer 147 may be disposed between the charge trap layer 144 and the stack structure ST. The blocking layer 147 may extend between the charge trap layer 144 and the plurality of horizontal electrodes 153 and between the charge trap layer 144 and the plurality of molding layers 152.

The drain pad 129 may be disposed on one surface (e.g., the lower surfaces) of the channel pattern 125 and the core layer 124. The drain pad 129 may be in direct contact with the channel pattern 125. The interlayer insulating layer 162 may be disposed on one surface (e.g., the lower surfaces) of the stack structure ST and the channel structure CH. The bit line 163 may be disposed in the interlayer insulating layer 162. The bit line 163 may be connected to the drain pad 129.

In an embodiment, the source line 171 may correspond to a common source line. The plurality of horizontal electrodes 153 may include a plurality of word lines, a plurality of select lines and at least one GIDL (gate-induced drain leakage) control line. Memory cells MC may be formed at intersections of the channel structure CH and the plurality of word lines. At least one of the plurality of horizontal electrodes 153 that is adjacent to the source line 171 may correspond to a source select line. At least one of the plurality of horizontal electrodes 153 that is adjacent to the drain pad 129 may correspond to a drain select line. One of the plurality of horizontal electrodes 153 that is adjacent to the source line 171 and/or one of the plurality of horizontal electrodes 153 that is adjacent to the drain pad 129 may correspond to the GIDL control line. The plurality of word lines may be disposed between at least one drain select line and at least one source select line among the plurality of horizontal electrodes 153.

FIG. 4 corresponds to a plan view taken by viewing a section (e.g., a section of the channel structure CH) of FIG. 3 on a plane that is defined in the first direction FD and the second direction SD according to embodiments of the present disclosure.

Referring to FIG. 4, the channel pattern 125 may surround the outer side of the core layer 124. The information storage pattern 149 may surround the outer side of the channel pattern 125. The tunnel layer 138 of the information storage pattern 149 may surround the outer side of the channel pattern 125 and may contact the outer side of the channel pattern 125. The charge trap layer 144 may surround the outer side of the tunnel layer 138 and may contact the outer side of the tunnel layer 138. The blocking layer 147 may surround the outer side of the charge trap layer 144 and may contact the outer side of the charge trap layer 144. The tunnel barrier layer 131 may surround the outer side of the channel pattern 125 and may contact the outer side of the channel pattern 125. The quantum wall 136 may surround the outer side of the tunnel barrier layer 131 and may contact the outer side of the tunnel barrier layer 131. The ferroelectric layer 137 may surround the outer side of the quantum wall 136 and may contact the outer side of the quantum wall 136.

Referring to FIG. 5, a semiconductor device according to embodiments of the present disclosure may include a stack structure ST, a channel structure CH, an interlayer insulating layer 162, a bit line 163, and a source line 171. FIG. 5 corresponds to a cross-sectional view taken on a plane that is defined in the first direction FD and the third direction VD according to embodiments of the present disclosure.

The channel structure CH may include a core layer 124, a channel pattern 125, a drain pad 129 and an information storage pattern 149. The information storage pattern 149 may include a tunnel layer 138, a charge trap layer 144 and a blocking layer 147. The tunnel layer 138 may include a first tunnel barrier layer 131, a first quantum wall 132, a second tunnel barrier layer 133, a second quantum wall 134, and a third tunnel barrier layer 135. The tunnel layer 138 may include a configuration similar to that described above with reference to FIG. 2.

In an embodiment, the first tunnel barrier layer 131 may be disposed between the channel pattern 125 and the first quantum wall 132. The first tunnel barrier layer 131 may contact the channel pattern 125. The first quantum wall 132 may be interposed between the first tunnel barrier layer 131 and the second tunnel barrier layer 133. The first quantum wall 132 may be in direct contact with the first tunnel barrier layer 131 and the second tunnel barrier layer 133. The second tunnel barrier layer 133 may be disposed between the first quantum wall 132 and the second quantum wall 134. The second tunnel barrier layer 133 may contact the first quantum wall 132 and the second quantum wall 134.

The second quantum wall 134 may be interposed between the second tunnel barrier layer 133 and the third tunnel barrier layer 135. The second quantum wall 134 may be in direct contact with the second tunnel barrier layer 133 and the third tunnel barrier layer 135. The third tunnel barrier layer 135 may be disposed between the second quantum wall 134 and the charge trap layer 144. The third tunnel barrier layer 135 may contact the charge trap layer 144.

FIG. 6 corresponds to a plan view taken by viewing a section (e.g., a section of the channel structure CH) of FIG. 5 on a plane that is defined in the first direction FD and the second direction SD according to embodiments of the present disclosure.

Referring to FIG. 6, the first tunnel barrier layer 131 may surround the outer side of the channel pattern 125. The first quantum wall 132 may surround the outer side of the first tunnel barrier layer 131. The second tunnel barrier layer 133 may surround the outer side of the first quantum wall 132. The second quantum wall 134 may surround the outer side of the second tunnel barrier layer 133. The third tunnel barrier layer 135 may surround the outer side of the second quantum wall 134. The charge trap layer 144 may surround the outer side of the third tunnel barrier layer 135.

Referring to FIG. 7, a semiconductor device according to embodiments of the present invention disclosure may include a second substrate 221, a circuit structure CS, a first insulating bonding layer 238, a plurality of first bonding pads 239, a stack structure ST, a buried insulating layer 156, a plurality of channel structures CH, a plurality of contact plugs 157, an interlayer insulating layer 162, a plurality of intermediate interconnections 163 and 164, a second insulating bonding layer 168, a plurality of second bonding pads 169, a source line 171, and an upper insulating layer 198.

The circuit structure CS may be disposed within the second substrate 221 and a circuit insulating layer 234. The circuit insulating layer 234 may be disposed on the second substrate 221. The circuit structure CS may include a page buffer PB, a decoder DE, an isolation layer 223, and the circuit insulating layer 234. In an embodiment, each of the page buffer PB and the decoder DE may include a plurality of transistors. The stack structure ST may include a plurality of molding layers 152 and a plurality of horizontal electrodes 153 that are alternately stacked in the third direction VD. Each of the plurality of channel structures CH may include a configuration similar to that illustrated in FIG. 3 to FIG. 6. The plurality of intermediate interconnections 163 and 164 may include a plurality of bit lines 163 which are connected to corresponding channel structures CH and a plurality of word line connecting interconnections 164 which are connected to corresponding contact plus 157.

A channel structure CH selected among the plurality of the channel structures CH may be connected to the page buffer PB via a corresponding bit line 163, a corresponding second bonding pad 169 and a corresponding first bonding pad 239. The page buffer PB may include, for example, a first gate electrode 226, a first source region 227 and a first drain region 229. The channel structure CH that is connected to the page buffer PB may be connected to the first drain region 229 of the page buffer PB.

A horizontal electrode 153 selected among the plurality of horizontal electrodes 153 may be connected to the decoder DE via a corresponding one among the plurality of contact plugs 157, a corresponding one among the plurality of word line connecting interconnections 164, a corresponding one among the plurality of second bonding pads 169 and a corresponding one among the plurality of first bonding pads 239. In an embodiment, the decoder DE may include a second gate electrode 246, a second source region 247 and a second drain region 249. The horizontal electrode 153 that is connected to the decoder DE may be connected to the second drain region 249 of the decoder DE.

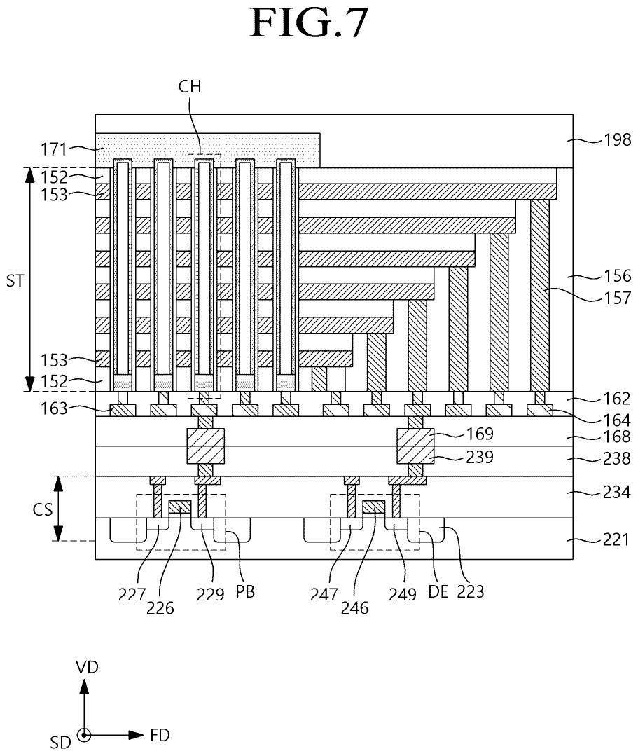

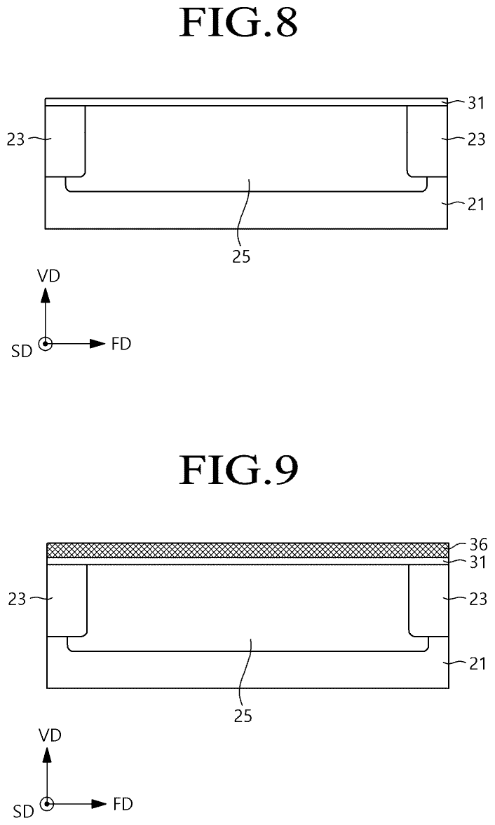

FIG. 8 to FIG. 12 are cross-sectional views illustrating a method of forming a semiconductor device according to embodiments of the present disclosure.

Referring to FIG. 8, an isolation layer 23 and a channel pattern 25 may be formed in a first substrate 21. The channel pattern 25 may be defined by the isolation layer 23. A tunnel barrier layer 31 may be formed on the channel pattern 25. The tunnel barrier layer 31 may also cover the top surfaces of the isolation layer 23.

The first substrate 21 may include a semiconductor substrate such as a silicon wafer or an SOI (silicon on insulator) wafer. The first substrate 21 may include a III-V group semiconductor substrate, for example, a compound semiconductor substrate such as gallium arsenide (GaAs). The first substrate 21 may include monocrystalline silicon, polysilicon, amorphous silicon, monocrystalline silicon germanium, polycrystalline silicon germanium, carbon-doped silicon, or a combination thereof. In an embodiment, the first substrate 21 may include a monocrystalline silicon wafer that has P-type impurities.

The isolation layer 23 may be formed using a trench isolation method. The isolation layer 23 may include a single layer or a multilayer. The isolation layer 23 may include at least two elements selected from the group consisting of silicon (Si), oxygen (O), nitrogen (N), carbon (C), boron (B), phosphorus (P) and hydrogen (H). Suitable materials for the isolation layer 23 may include silicon oxide, silicon nitride, silicon oxynitride, silicon carbon nitride (SiCN), silicon oxycarbon nitride (SiOCN), a low-k dielectric, a high-k dielectric, or a combination thereof.

The channel pattern 25 may be delimited by the isolation layer 23 in the first substrate 21. The channel pattern 25 may be formed to a predetermined depth from the upper surface of the first substrate 21. In an embodiment, the channel pattern 25 may include a monocrystalline silicon layer that has P-type impurities.

The tunnel barrier layer 31 may include silicon oxide, aluminum oxide, silicon nitride (Si3N4), boron nitride (BN), titanium oxide (TiO2), zirconium oxide (ZrO2), magnesium oxide (MgO), gallium nitride (GaN), or a combination thereof. Forming the tunnel barrier layer 31 may include an atomic layer deposition (ALD) method, a cyclic deposition method, a chemical vapor deposition (CVD) method, or a combination thereof. The tunnel barrier layer 31 may be formed to cover the channel pattern 25 with a uniform thickness. The tunnel barrier layer 31 may extend onto the isolation layer 23. The tunnel barrier layer 31 may have a thickness of 0.5 nm to 10 nm.

Referring to FIG. 9, a quantum wall 36 may be formed on the tunnel barrier layer 31. The quantum wall 36 may include tantalum pentoxide (Ta₂O₅), aluminum nitride (AlN), zirconium oxide (ZrO₂), strontium titanate (SrTiO₃), yttrium oxide (Y₂O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof. Forming the quantum wall 36 may include an atomic layer deposition (ALD) method, a cyclic deposition method, a chemical vapor deposition (CVD) method, a sputtering method, a physical vapor deposition (PVD) method, or a combination thereof. The quantum wall 36 may cover the tunnel barrier layer 31. The quantum wall 36 may have a thickness of 0.5 nm to 20 nm. In an embodiment, the quantum wall 36 may be thicker than the tunnel barrier layer 31.

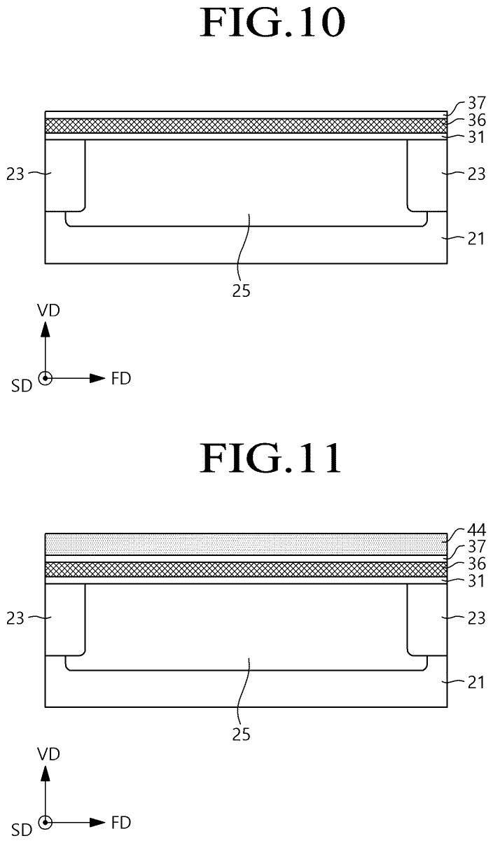

Referring to FIG. 10, a ferroelectric layer 37 may be formed on the quantum wall 36. The ferroelectric layer 37 may cover the quantum wall 36. The ferroelectric layer 37 may include hafnium oxide (HfO₂), hafnium zirconium oxide (HfZrO₂), lead zirconate titanate (PZT), bismuth ferrite (BiFeO₃), strontium bismuth tantalate (SBT: SrBi2Ta₂O₉), lithium niobate (LiNbO₃), barium titanate (BaTiO₃), titanium nitride (TiN), zirconium oxide (ZrO₂), strontium titanate (SrTiO₃), hafnium oxide doped with silicon (Si) or aluminum (Al), or a combination thereof. Forming the ferroelectric layer 37 may include an atomic layer deposition (ALD) method, a cyclic deposition method, a chemical vapor deposition (CVD) method, a sputtering method, a physical vapor deposition (PVD) method, or a combination thereof. The ferroelectric layer 37 may cover the quantum wall 36 and may have a thickness of 0.5 nm to 10 nm.

Referring to FIG. 11, a charge trap layer 44 may be formed on the ferroelectric layer 37. The charge trap layer 44 may cover the ferroelectric layer 37. The charge trap layer 44 may have a thickness of 1 nm to 30 nm. In an embodiment, the charge trap layer 44 may be thicker than each of the tunnel barrier layer 31 and the ferroelectric layer 37. The charge trap layer 44 may include silicon nitride. Forming the charge trap layer 44 may include an atomic layer deposition (ALD) method, a cyclic deposition method, a chemical vapor deposition (CVD) method, or a combination thereof.

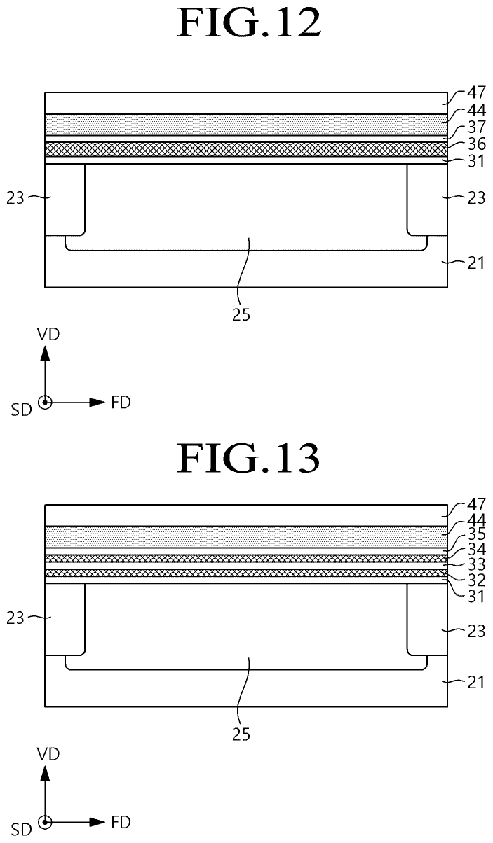

Referring to FIG. 12, a blocking layer 47 may be formed on the charge trap layer 44. The blocking layer 47 may cover the charge trap layer 44. The blocking layer 47 may cover the charge trap layer 44 and may have a thickness of 3 nm to 30 nm. In an embodiment, a thickness of the blocking layer 47 may be greater than a thickness of each of the tunnel barrier layer 31 and the ferroelectric layer 37 layers. The blocking layer 47 may include an aluminum oxide layer (Al₂O₃). Forming the blocking layer 47 may include an atomic layer deposition (ALD) method, a cyclic deposition method, a chemical vapor deposition (CVD) method, a sputtering method, a physical vapor deposition (PVD) method, or a combination thereof.

Referring again to FIG. 1, a top electrode 56 may be formed on the blocking layer 47. By using a patterning process, the top electrode 56, the blocking layer 47, the charge trap layer 44, the ferroelectric layer 37, the quantum wall 36 and the tunnel barrier layer 31 may be partially removed. By using an ion implantation process, a source region 27 and a drain region 29 may be formed. The channel pattern 25 may be delimited between the source region 27 and the drain region 29.

In an embodiment, each of the source region 27 and the drain region 29 may include a monocrystalline silicon layer that has N-type impurities. The top electrode 56 may include a single layer or a multilayer. The top electrode 56 may include a conductive material such as metal, metal nitride, metal oxide, metal silicide, polysilicon, conductive carbon, or a combination thereof. The top electrode 56 may include W, WN, Ti, TiN, Ta, TaN, Ni, Co, Ru, Sn, Pt, Au, Ag, Cu, Al, or a combination thereof.

FIG. 13 is a cross-sectional view illustrating a method of forming a semiconductor device according to embodiments of the present disclosure.

Referring to FIG. 13, an isolation layer 23 and a channel pattern 25 may be formed in a first substrate 21. A first tunnel barrier layer 31, a first quantum wall 32, a second tunnel barrier layer 33, a second quantum wall 34, a third tunnel barrier layer 35, a charge trap layer 44 and a blocking layer 47 may be sequentially stacked on the isolation layer 23 and the channel pattern 25.

Each of the first tunnel barrier layer 31, the second tunnel barrier layer 33 and the third tunnel barrier layer 35 may include silicon oxide, aluminum oxide, silicon nitride (Si3N4), boron nitride (BN), titanium oxide (TiO2), zirconium oxide (ZrO2), magnesium oxide (MgO), gallium nitride (GaN), or a combination thereof. Each of the first tunnel barrier layer 31, the second tunnel barrier layer 33 and the third tunnel barrier layer 35 may have a thickness of 0.5 nm to 5 nm.

Each of the first quantum wall 32 and the second quantum wall 34 may include tantalum pentoxide (Ta2O5), aluminum nitride (AlN), zirconium oxide (ZrO2), strontium titanate (SrTiO3), yttrium oxide (Y2O3), lanthanum oxide (La2O3), scandium oxide (Sc2O3), gallium oxide (Ga2O3), gadolinium oxide (Gd2O3), silicon nitride (Si3N4), or a combination thereof. Each of the first quantum wall 32 and the second quantum wall 34 may have a thickness of 0.5 nm to 7 nm.

Referring again to FIG. 2, a top electrode 56 may be formed on the blocking layer 47. By using a patterning process, the top electrode 56, the blocking layer 47, the charge trap layer 44, the third tunnel barrier layer 35, the second quantum wall 34, the second tunnel barrier layer 33, the first quantum wall 32 and the first tunnel barrier layer 31 may be partially removed. By using an ion implantation process, a source region 27 and a drain region 29 may be formed.

Referring again to FIG. 7, a circuit structure CS may be formed on a second substrate 221. A first insulating bonding layer 238 and a plurality of first bonding pads 239 may be formed on the circuit structure CS. The second substrate 221 may include a configuration similar to that of the first substrate 21 described above with reference to FIG. 8. The circuit structure CS may be formed in and/or on the second substrate 221.

The circuit structure CS may include various types of active/passive elements such as transistors. A transistor may include a planar transistor, a recess channel transistor, a vertical transistor, a fin field effect transistor (finFET), a gate all around (GAA) transistor, a multi-bridge channel transistor, or a combination thereof. In an embodiment, the circuit structure CS may include a page buffer PB, a decoder DE, an isolation layer 223, and a circuit insulating layer 234. The page buffer PB may include a first gate electrode 226, a first source region 227 and a first drain region 229. The decoder DE may include a second gate electrode 246, a second source region 247 and a second drain region 249.

The circuit insulating layer 234 may be formed on the second substrate 221 to cover the page buffer PB and the decoder DE. The first insulating bonding layer 238 may cover the circuit structure CS. The plurality of first bonding pads 239 may be formed in the first insulating bonding layer 238. The upper surfaces of the first insulating bonding layer 238 and the plurality of first bonding pads 239 may form substantially the same plane. Each of the plurality of first bonding pads 239 may be electrically connected to a corresponding at least one of the page buffer PB and the decoder DE.

A second insulating bonding layer 168, a plurality of second bonding pads 169, an interlayer insulating layer 162, a plurality of intermediate interconnections 163 and 164, a stack structure ST, a buried insulating layer 156, a plurality of channel structures CH, a plurality of contact plugs 157, a source line 171, and an upper insulating layer 198 may be formed on the first insulating bonding layer 238 and the plurality of first bonding pads 239. The first insulating bonding layer 238 and the second insulating bonding layer 168 may be bonded to face each other, and the plurality of first bonding pads 239 and the plurality of second bonding pads 169 may be bonded to face each other.

The stack structure ST may include a plurality of molding layers 152 and a plurality of horizontal electrodes 153 that are alternately stacked in the third direction VD. Each of the plurality of channel structures CH may include a configuration similar to that illustrated in FIG. 3 to FIG. 6. The plurality of intermediate interconnections 163 and 164 may include a plurality of bit lines 163 and a plurality of word line connecting interconnections 164.

The channel pattern 125 may include a semiconductor layer such as a polysilicon layer. Each of a drain pad 129 and the source line 171 may include a conductive material such as polysilicon, metal, metal nitride, metal silicide, or a combination thereof.

Each of the plurality of horizontal electrodes 153, the plurality of contact plugs 157, the plurality of intermediate interconnections 163 and 164, the plurality of second bonding pads 169, the first gate electrode 226, the plurality of first bonding pads 239 and the second gate electrode 246 may include a conductive material such as polysilicon, metal, metal nitride, metal silicide, conductive carbon, or a combination thereof. Each of the plurality of horizontal electrodes 153, the plurality of contact plugs 157, the plurality of intermediate interconnections 163 and 164, the plurality of second bonding pads 169, the first gate electrode 226, the plurality of first bonding pads 239 and the second gate electrode 246 may include copper (Cu), aluminum (Al), nickel (Ni), cobalt (Co), ruthenium (Ru), tungsten (W), tungsten nitride (WN), titanium (Ti), titanium nitride (TiN), tantalum (Ta), tantalum nitride (TaN), zirconium (Zr), hafnium (Hf), tin (Sn), platinum (Pt), gold (Au), silver (Ag), or a combination thereof. In an embodiment, each of the plurality of first bonding pads 239 and the plurality of second bonding pads 169 may include a copper layer.

Each of the core layer 124, the plurality of molding layers 152, the buried insulating layer 156, the interlayer insulating layer 162, the second insulating bonding layer 168, the upper insulating layer 198, the isolation layer 223, the circuit insulating layer 234 and the first insulating bonding layer 238 may include a single layer or a multilayer. Each of the core layer 124, the plurality of molding layers 152, the buried insulating layer 156, the interlayer insulating layer 162, the second insulating bonding layer 168, the upper insulating layer 198, the isolation layer 223, the circuit insulating layer 234 and the first insulating bonding layer 238 may include at least two selected from the group consisting of silicon (Si), oxygen (O), nitrogen (N), carbon (C), boron (B), phosphorus (P) and hydrogen (H). Each of the core layer 124, the plurality of molding layers 152, the buried insulating layer 156, the interlayer insulating layer 162, the second insulating bonding layer 168, the upper insulating layer 198, the isolation layer 223, the circuit insulating layer 234 and the first insulating bonding layer 238 may include silicon oxide, silicon nitride, silicon oxynitride, silicon carbon nitride (SiCN), silicon oxycarbon nitride (SiOCN), a low-k dielectric, a high-k dielectric, or a combination thereof.

While the detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments can be combined to form additional embodiments.

What is claimed is:

1. A semiconductor device comprising:
a channel pattern;
an electrode over the channel pattern; and
an information storage pattern between the channel pattern and the electrode,
the information storage pattern comprising,
a charge trap layer;
a blocking layer between the charge trap layer and the electrode;
a first tunnel barrier layer disposed between the charge trap layer and the channel pattern; and
a first quantum wall disposed between the charge trap layer and the first tunnel barrier layer,
wherein the first tunnel barrier layer includes a material having a higher energy barrier than the charge trap layer, and
the first quantum wall includes a material having a lower energy barrier than the first tunnel barrier layer.

2. The semiconductor device according to claim 1, wherein the first quantum wall includes a material with a lower energy barrier than the charge trap layer.

3. The semiconductor device according to claim 1, wherein the first quantum wall includes tantalum pentoxide (Ta₂O₅), aluminum nitride (AlN), zirconium oxide (ZrO₂), strontium titanate (SrTiO₃), yttrium oxide (Y₂O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof.

4. The semiconductor device according to claim 1, wherein the first tunnel barrier layer includes silicon oxide, aluminum oxide (Al₂O₃), silicon nitride (Si₃N₄), boron nitride (BN), titanium oxide (TiO₂), zirconium oxide (ZrO₂), magnesium oxide (MgO), gallium nitride (GaN), or a combination thereof.

5. The semiconductor device according to claim 1, further comprising
a ferroelectric layer disposed between the charge trap layer and the first quantum wall.

6. The semiconductor device according to claim 5, wherein the ferroelectric layer includes a material with a lower energy barrier than the first tunnel barrier layer.

7. The semiconductor device according to claim 5, wherein the ferroelectric layer includes a material with a higher energy barrier than the first quantum wall.

8. The semiconductor device according to claim 5, wherein the ferroelectric layer includes a material with a higher energy barrier than the charge trap layer.

9. The semiconductor device according to claim 5, wherein the ferroelectric layer includes hafnium oxide (HfO₂), hafnium zirconium oxide (HfZrO₂), lead zirconate titanate (PZT), bismuth ferrite (BiFeO₃), strontium bismuth tantalate (SBT: SrBi₂Ta₂O₉), lithium niobate (LiNbO₃), barium titanate (BaTiO₃), titanium nitride (TiN), zirconium oxide (ZrO₂), strontium titanate (SrTiO₃), hafnium oxide doped with silicon (Si) or aluminum (Al), or a combination thereof.

10. The semiconductor device according to claim 1, further comprising:
a second tunnel barrier layer disposed between the charge trap layer and the first quantum wall;
a second quantum wall disposed between the charge trap layer and the second tunnel barrier layer; and
a third tunnel barrier layer disposed between the charge trap layer and the second quantum wall.

11. The semiconductor device according to claim 10, wherein each of the second tunnel barrier layer and the third tunnel barrier layer includes a material with a higher energy barrier than the charge trap layer.

12. The semiconductor device according to claim 10, wherein each of the second tunnel barrier layer and the third tunnel barrier layer includes silicon oxide, aluminum oxide (Al₂O₃), silicon nitride (Si₃N₄), boron nitride (BN), titanium oxide (TiO₂), zirconium oxide (ZrO₂), magnesium oxide (MgO), gallium nitride (GaN), or a combination thereof.

13. The semiconductor device according to claim 10, wherein the second quantum wall includes a material with a lower energy barrier than the second tunnel barrier layer.

14. The semiconductor device according to claim 10, wherein the second quantum wall includes a material with a lower energy barrier than the charge trap layer.

15. The semiconductor device according to claim 10, wherein the second quantum wall includes tantalum pentoxide (Ta₂O₅), aluminum nitride (AlN), zirconium oxide (ZrO₂), strontium titanate (SrTiO₃), yttrium oxide (Y₂O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof.

16. A semiconductor device comprising:
a stack structure having a plurality of molding layers and a plurality of horizontal electrodes that are alternately stacked;
a source line on the stack structure; and
a channel structure passing through the stack structure and extending into the source line,
the channel structure comprising a channel pattern contacting the source line; and
an information storage pattern between the channel pattern and the stack structure,
the information storage pattern comprising a charge trap layer;
a blocking layer between the charge trap layer and the stack structure;
a first tunnel barrier layer disposed between the charge trap layer and the channel pattern, and
a first quantum wall disposed between the charge trap layer and the first tunnel barrier layer,
wherein the first tunnel barrier includes a material with a higher energy barrier than the charge trap layer, and
the first quantum wall includes a material with a lower energy barrier than the first tunnel barrier layer.

17. The semiconductor device according to claim 16, wherein the first quantum wall includes a material with a lower energy barrier than the charge trap layer.

18. The semiconductor device according to claim 16, wherein the first quantum wall includes tantalum pentoxide (Ta₂O₅), aluminum nitride (AlN), zirconium oxide (ZrO₂), strontium titanate (SrTiO₃), yttrium oxide (Y₂O₃), lanthanum oxide (La₂O₃), scandium oxide (Sc₂O₃), gallium oxide (Ga₂O₃), gadolinium oxide (Gd₂O₃), silicon nitride (Si₃N₄), or a combination thereof.

19. The semiconductor device according to claim 16, further comprising
a ferroelectric layer disposed between the charge trap layer and the first quantum wall.

20. The semiconductor device according to claim 16, further comprising:
a second tunnel barrier layer disposed between the charge trap layer and the first quantum wall;
a second quantum wall disposed between the charge trap layer and the second tunnel barrier layer; and
a third tunnel barrier layer disposed between the charge trap layer and the second quantum wall.
